(19) United States
(12) Patent Application Publication
(10) Pub. No.: US 2008/0063494 A1
(43) Pub. Date: Mar. 13, 2008

(54) Sheet sticking apparatus

(75) Inventors: Kan Nakata, Tokyo (JP); Kenji Kobayashi, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: LINTEC CORPORATION, Tokyo (JP)

(21) Appl. No.: 11/896,971

(22) Filed: Sep. 7, 2007

(30) Foreign Application Priority Data
Sep. 8, 2006 (JP) 2006-244673

(51) Int. Cl. H01L 21/67

(52) U.S. Cl. 414/225.01

(57) ABSTRACT

A sheet sticking apparatus 10 is so arranged as to include a table 11 for supporting a semiconductor wafer W, and a pressing member 12 for pressing down a sheet S disposed along the semiconductor wafer W. The pressing member 12 includes a pressing surface 21 arranged to have an inclined surface or curved-form where a central area is closer to a semiconductor wafer W than a peripheral side, and a deformable portion 23 connected to the peripheral side thereof. The deformable portion 23 is adapted to be deformable caused by decompression difference within a second space S2 formed between the pressing member 12 and an upper case 30. The deformation of the deformable portion 23 causes the surface position of the pressing surface 21 to come down, and the distribution of the pressing force is spread from the central area toward the peripheral side, thereby exerting a sticking pressure to the sheet S.

### BACKGROUND OF THE INVENTION

1. Field of the Invention

The present invention relates to a sheet sticking apparatus, more particularly, to a sheet sticking apparatus capable of, when a sheet is stuck to a plate-like member such as a semiconductor wafer, sticking the sheet without trapping air between the sheet and the plate-like member.

2. Background Art

Conventionally, it has been the practice to stick to a semiconductor wafer (hereinafter referred simply to as “wafer”), a protective sheet for protecting a circuit surface thereof, or to stick an adhesive sheet for die bonding to a back surface thereof.

An arrangement is disclosed in a patent document 1, wherein a pressing member provided with a curved-form where a central area protrudes relatively from a peripheral side is used as a member to impart a pressing force to a sheet for preventing trapping of air between the wafer and the sheet. The pressing member is arranged to use an elastically deformable raw material, and the pressing member is fixed to the tip of a piston rod of air cylinder. When the sheet is to be stuck, the sheet sticking is arranged to be performed gradually from the central area toward the outer side by extending the piston rod to impart the pressing force by the pressing member.

[Patent Document 1] Japanese Patent No. 2945089

### SUMMARY OF THE INVENTION

### Problem to be Solved by the Invention

The pressing member disclosed in the patent document 1 is, however, enabled to move up or down by the air cylinder, resulting in that there are some disadvantages: that is, the number of parts increases; an apparatus becomes larger in size; and further measures are also required for preventing vacuum (decompression) leakage from joining portions of these parts.

Further, the pressing member disclosed in the patent document 1 is comprised of elastically deformable raw material that forms into a cross-sectional shape where wall thickness in a central area is thicker than that in a peripheral side. As a result, when a pressing force is exerted to the sheet on all regions of the wafer, the pressing force applied to the central area of the wafer becomes stronger than that to the peripheral side of the wafer. Accordingly, there is a disadvantage that poor sticking is more likely to occur, due to the fact that a sheet pressing force to the peripheral side of the wafer becomes relatively weaker. On the other hand, if a sheet pressing force to the peripheral side of the wafer is fully exercised, it brings about a tendency that the pressing force to the central area becomes excessive thereby inviting a disadvantage that the wafer is apt to be broken.

### OBJECT OF THE INVENTION

The present invention has been devised in view of such disadvantages. It is an object of the present invention to provide a sheet sticking apparatus capable of reducing the number of parts of an apparatus itself, achieving the reduction in size of the apparatus, as well as eliminating the trapping of air into the plate-like member thereby ensuring reliable sticking of the sheet, and avoiding damages of a plate-like member as well.

### Means for Solving Problems

In order to achieve the above-described object, the present invention employs an arrangement, in which a sheet sticking apparatus comprises: a table for supporting a plate-like member; and a pressing member for exerting a pressing force to a sheet disposed along the plate-like member: wherein the pressing member includes: a pressing surface arranged to have an inclined surface or a curved-form where central area thereof is closer to the plate-like member than peripheral side; and a deformable portion being connected to a peripheral side of the pressing surface; and wherein the pressing surface is brought into close proximity with the sheet by causing the deformable portion to be deformed with respect to an initial shape, and the sheet is stuck to the plate-like member from central area toward peripheral side by causing the pressing surface to be deformed so as to be substantially parallel with respect to the plate-like member.

Further, the present invention may employ an arrangement, in which a sheet sticking apparatus comprises: a table for supporting a plate-like member; and a pressing member for exerting a pressing force to a sheet disposed along the plate-like member: wherein

the pressing member includes: a pressing surface arranged to have an inclined surface or a curved-form where one end thereof is closer to the plate-like member than the other end; and a deformable portion being connected to the pressing surface; and wherein

the pressing surface is brought into close proximity with the sheet by causing the deformable portion to be deformed with respect to an initial shape, and the sheet is stuck to the plate-like member from the one end toward the other end by causing the pressing surface to be deformed so as to be substantially parallel with respect to the plate-like member.

In the present invention, an arrangement may be employed in which the pressing surface is substantially conical in shape; and the deformable portion is provided in flexural shape being continued to the peripheral portion of the pressing surface.

Also, in the present invention, an arrangement is preferably employed in which:

a lower case of upper open type for accommodating the table; and an upper case of lower open type for accommodating the pressing member are further included,

a first space is formed by the upper and lower cases and the pressing member, whereas a second space is formed by the upper case and the pressing member; and

when the sheet is stuck to the plate-like member by pressing down the sheet, the first and second spaces are kept in decompression or substantially vacuum state, whereas the second space is gradually released from the decompression or substantially vacuum state, thereby causing the deformable portion to be deformed.

Further, the present invention may also employ an arrangement, in which a lower case of upper open type for accommodating the table; and an upper case of lower open type for accommodating the pressing member are further included, wherein

a first space is formed by the upper and lower cases and the pressing member, whereas a second space is formed by the pressing member; and

when the sheet is stuck to the plate-like member by pressing down the sheet, the first and second spaces are kept in decompression or substantially vacuum state, whereas the second space is gradually released from the decompression or substantially vacuum state, thereby causing the deformable portion to be deformed.

Furthermore, the deformable portion includes zigzag regions, and as the second space is gradually released from decompression or substantially vacuum state, the deformable portion undergoes angular displacement or extensional deformation.

Still further, the deformable portion is comprised of such a material that undergoes more readily elastic deformation than the pressing surface, and as the second space is gradually released from decompression or substantially vacuum state, the deformable portion can be so arranged as to undergo elastic deformation.

### EFFECT OF THE INVENTION

According to the present invention, a pressing surface is so arranged as to approach to a sheet as the deformable portion is deformed, and as a result, the need for an air cylinder for moving up or down the pressing member as disclosed in the patent document 1, or a sealing member for preventing the leakage of vacuum (pressure reduction) from joining sections of their parts can be eliminated, and the number of parts can be reduced, and reduction in size of an apparatus can be achieved. Furthermore, from this state, the pressing surface is so arranged as to stick the sheet from the central area toward peripheral portion of the plate-like member. Accordingly, sticking of the sheet can be carried out while expelling air between the plate-like member and the sheet. Therefore, sticking of the sheet to the plate-like member can be ensured by eliminating the trapping of air.

Also, since the deformable portion is provided in a flexural shape, it becomes possible to displace the position of the pressing surface by displacing the flexural shape, and thus the pressing surface can be moved while restraining the deformation of the pressing surface itself.

Further, with the help of such an arrangement in which the table and the pressing member are accommodated within the lower case and the upper case and the pressure can be reduced, the trapping of air between the plate-like member and the sheet can be minimized by maintaining the first space containing the plate-like member and the sheet to be substantially vacuum. In addition, by virtue of such an arrangement in which the second space is to be deformed by utilizing the pressure reduction, a driving source such as an air cylinder as cited in the patent document 1 is not required, and also the need for pressurized air source to actuate it can be eliminated, as well as the relevant control can be performed with ease, and it becomes possible to reduce manufacturing cost and running cost of the apparatus.

Also, in the case where the deformable portion is so arranged as to include zigzag regions, or comprised of a material that readily undergoes elastic deformation, a larger deformation margin can be ensured by utilizing extension and contraction thereof.

### BRIEF DESCRIPTION OF THE DRAWINGS

FIG. 1 is a schematic sectional view of a sheet sticking apparatus according to an embodiment of the present invention.

FIG. 2 is a partially cut-away perspective view of a pressing member.

FIG. 3 is a schematic sectional view illustrating a state where an initial operation of a sheet sticking is completed.

FIG. 4 is a schematic sectional view illustrating a state immediately after a sheet sticking has been started.

FIG. 5 is a schematic sectional view illustrating a state where a deformable portion is deformed and a pressing surface is flattened.

FIG. 6 is a schematic sectional view illustrating a state where a sheet has been completely stuck to a wafer.

FIG. 7 is a schematic sectional view illustrating another example of a deformable portion.

### BEST MODE FOR CARRYING OUT THE INVENTION

Hereinafter, referring to the drawings, preferred embodiments of the present invention will be described.

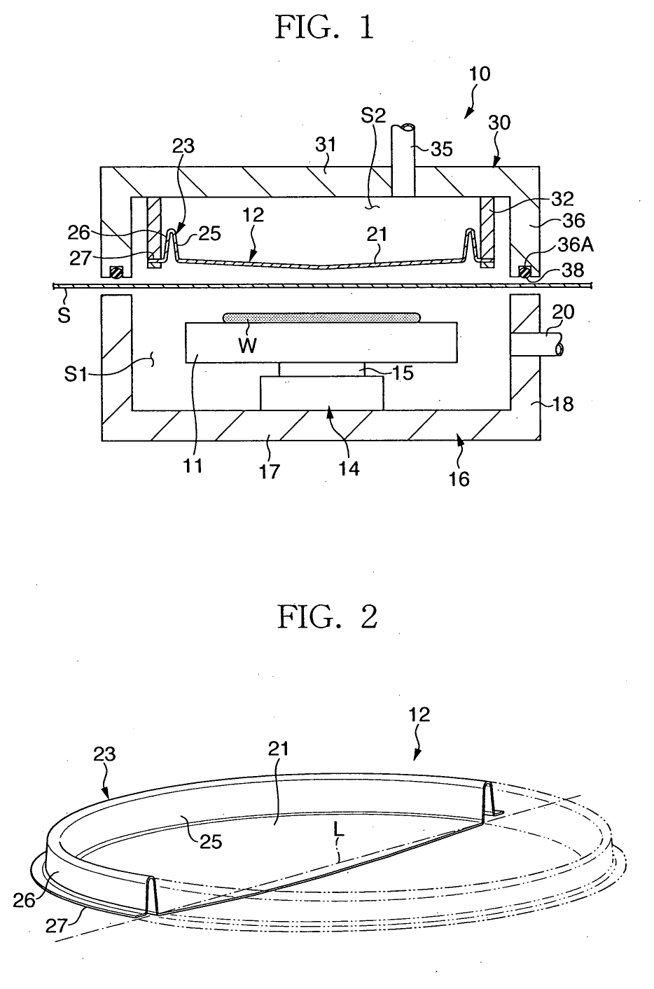

FIG. 1 illustrates a schematic front view of a sheet sticking apparatus according to the embodiment of the present invention. In this figure, a sheet sticking apparatus 10 is arranged so as to include a table 11 for supporting a wafer W serving as a plate-like member, and a pressing member 12 for exerting a pressing force to a sheet S disposed along a top face of the wafer W as shown in this figure. Here, the sheet S is not limited in particular, but in the embodiment of the present invention, a sheet for protecting a circuit surface formed on a front surface (top face) of the wafer W is employed, and an adhesive layer is provided on a lower surface side thereof.

The table 11 is so provided as to be able to support the wafer W fixedly on a top surface thereof. The table 11 is fixed on a top end of a rod 15 of a uni axial robot 14, and is designed to be able to move up and down by an extending and retracting mechanism of the rod 15. In the present embodiment, the uni axial robot 14 is disposed on a bottom wall 17 of a lower case 16, and thereby the table 11 is so arranged as to be accommodated within the lower case 16. The lower case 16 is cylindrical in shape with a bottom plate, and a piping 20 is connected from a peripheral wall 18 to a decompression source (not shown), and thus level of decompression thereof is designed to be controllable.

The pressing member 12 is comprised of a molded component using rubber. The pressing member 12 is, as shown in FIG. 2, arranged such that a central area is positioned toward gradually lower level relative to a peripheral portion with respect to a horizontal line L. That is, the pressing member 12 includes a pressing surface 21 formed in conical shape and provided in an inclined surface or curved-form where the central area is positioned closer to the wafer W than the peripheral side, and a deformable portion 23 in flexural shape continued to a peripheral side of the pressing surface 21 and extending in circumferential direction.

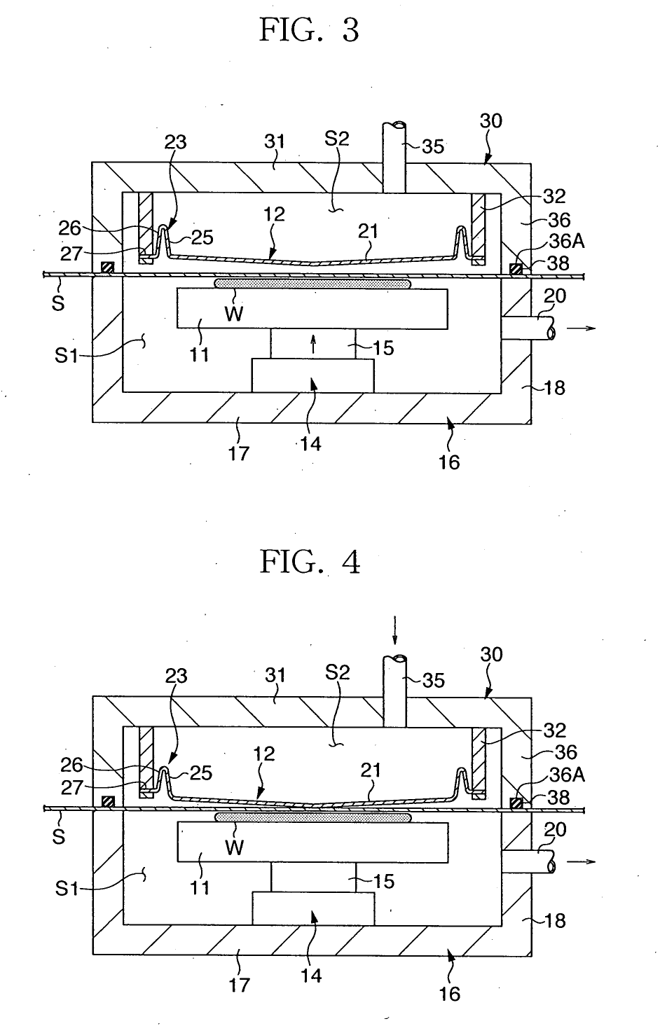

The deformable portion 23 includes an inner erecting surface 25 directed upward from the peripheral portion of the pressing surface 21, a peripheral drooping surface 26 running downward at acute angle from the top end of the inner erecting surface 25, and a flange surface portion 27 being formed at the lower end of the peripheral drooping surface 26. The flange surface portion 27 is fixed via a screw (not shown) at the lower end of a mounting cylinder 32 fixed in a lower surface of a top wall 31 forming an upper case 30 of lower open type. Thereby, when the upper and lower cases 30, 16 are enclosed, a first space S1 is designed to be formed by these cases 30, 16 and the pressing member 12, whereas a second space S2 to be formed by the top wall 31 portion of the upper case 30, the pressing member 12 and the mounting cylinder 32. It is noted that, in FIG. 1, although the top end of the lower case 16 is illustrated as being enclosed by the sheet S, width dimension of the sheet S along an orthogonal direction to paper surface in the figure is smaller than inner diameter dimension of the lower case 16. Consequently, even in a state in which the upper and lower cases 30, 16 are enclosed in alignment with each other (refer to FIG. 3), an internal region excluding the second space S2 is intended to form a lower space S1.

The upper case 30 is provided with a piping 35 connected to a top wall 31 thereof, and the piping 35 is connected to a decompression source (not shown) adapted to decompress within the second space S2, which is designed to be capable of controlling the level of decompression thereof. It is noted that a recessed groove 36A is formed at the lower end surface of a peripheral wall 36 in the upper case 30, and an O-ring 38 is housed within the recessed groove 36A thereby ensuring a sealing property when the upper and lower cases 30, 16 are butt-enclosed.

Now, a method of sticking the sheet in the embodiment of the present invention will be described with reference to FIGS. 3 through 6.

First, in an opened state where the upper case 30 is separated from the upper end of the lower case 16, a wafer W is transferred to a table 11 via a transfer arm (not shown) or the like. At that time, a sheet S is supplied across between the upper and lower cases 30, 16 via a sheet supply apparatus (not shown), and thereby an initial operation for sticking the sheet S is completed.

Subsequent to completion of the initial operation, as illustrated in FIG. 3, the upper and lower cases 30, 16 are enclosed in alignment with each other, and then the rod 15 of the uni axial robot 14 is extended so that the wafer W is moved upward to a position where the top surface of the wafer W reaches the proximity of the lower surface of the sheet S, and further a predetermined decompression state is attained while controlling so that the first and second spaces S1, S2 are bought about in approximately the same decompression state. Next, while the first space S1 is held under the predetermined decompression state, the decompression state of only the second space S2 is gradually released (brought close to atmospheric pressure).

When the pressing member 12 receives downward force exerted to the pressing surface 21, resulting from the release of the decompression, the deformable portion 23 begins to be deformed, as illustrated in FIG. 4. The deformation causes surface position of the pressing surface 21 to be pushed down, and thus the central area of the pressing surface 21 is adapted to press down the sheet S, resulting in that sticking of the sheet S to the central part of the wafer W is carried out.

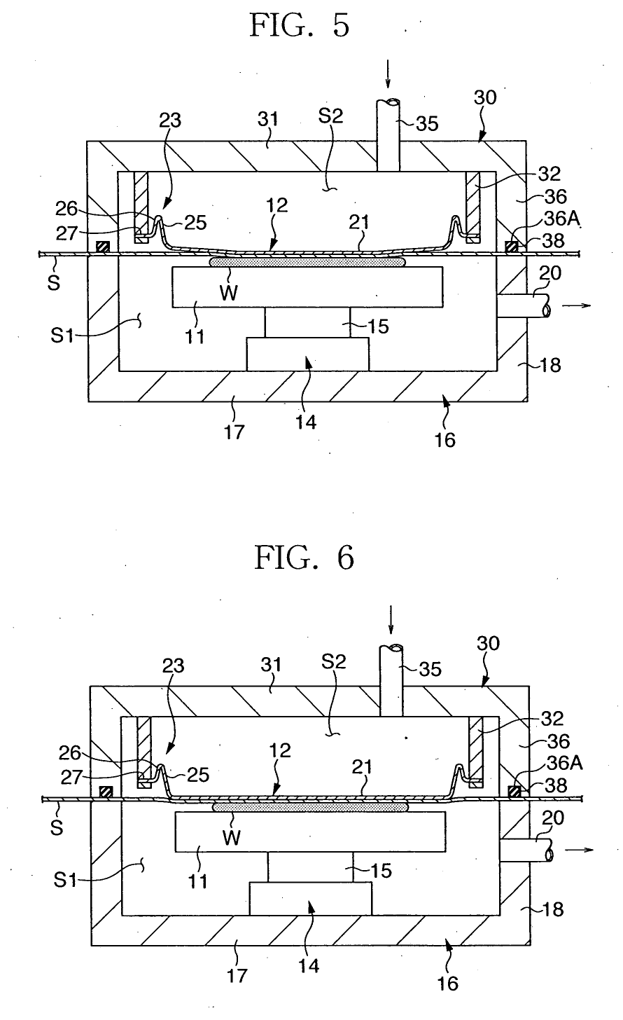

The deformable portion 23 continues to be deformed, as illustrated in FIG. 5, by further release of decompression of the second space S2, and accordingly inclined surface of the pressing surface 21 is pressed against the wafer W side, thereby ensuring to stick the sheet S to the wafer W gradually from the central area toward the peripheral side. Finally, as illustrated in FIG. 6, the pressing surface 21 is so deformed as to be nearly parallel with the wafer W, and consequently sticking operation of the sheet S is carried out to the whole region of top surface of the wafer W.

Subsequent to the completion of sticking of the sheet S in this manner, the upper and lower cases 30, 16 are opened, and cutting operation of the sheet S is performed by a cutting apparatus (not shown) along a peripheral side of the wafer W.

Therefore, according to such an embodiment, since the first and the second spaces S1, S2 are put in approximately the same decompression state, the deformable portion 23 is deformed by gradually releasing only the second space S2 side from decompression state. The pressing surface 21 is flattened by this deformation step by step from the central area toward the peripheral side, and thereby sticking of the sheet S is carried out. By virtue of this arrangement, it becomes possible to stick the sheet S to the wafer W by utilizing only decompression, and further even if air is present between the sheet S and the wafer W, it becomes possible to perform sticking operation of the sheet S while expelling the air to the outside. Thus, the invention offers the effectiveness that sticking of the sheet S can be ensured without trapping air.

As was described up to this point, the best arrangement, method and the like for carrying out the present invention have been disclosed in the foregoing descriptions. However, the present invention is not limited to the details set forth.

That is, the present invention has been illustrated and described mainly with reference to a specific embodiment. However, the invention is intended to cover such various modifications or changes that those skilled in the art may add, if necessary, to the above-described embodiment with respect to shape, location, layout and the like without departing from the technical spirit and the scope of the object of the present invention.

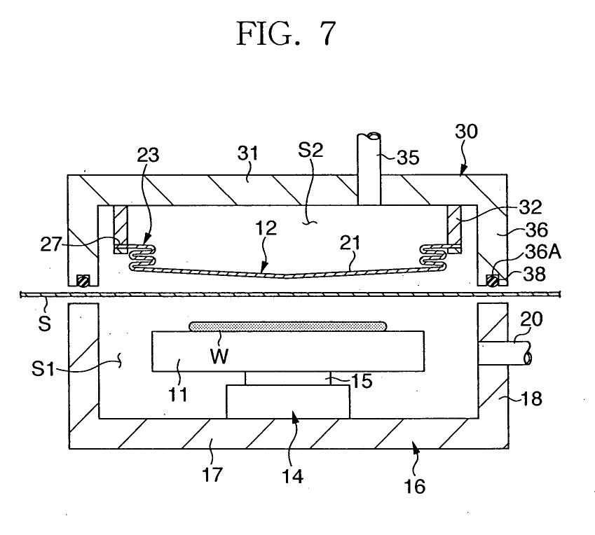

For example, in the above-described embodiment, there has been illustrated and described a case where the deformable portion 23 includes an inner erecting surface 25 directed to an erecting direction from the peripheral portion of the pressing surface 21, and a peripheral drooping portion 26 along a downward line at acute angle from the top of the inner erecting surface 25. As illustrated in FIG. 7, however, an accordion (bellow)-shaped deformable portion 23 may be formed, which is arranged in zigzag in lateral direction from the peripheral portion of the pressing surface 21. In this arrangement, when relative pressure of the second space S2 is increased, the deformable portion 23 is stretched vertically, and then the inclined surface of the pressing surface 21 is pressed down to the wafer W side, and is gradually deformed so as to be nearly parallel with the wafer W, thereby performing the sticking of the sheet S.

Further, by using a material that more readily undergoes elastic deformation than the pressing surface 21 for the deformable portion 23, that is, by changing the hardness of rubber serving as a material, as in the case of the present embodiment, the deformable portion 23 may be arranged so as to be more readily stretched vertically when pressure of the second space S2 is relatively increased.

Also, in the above-described embodiment, an arrangement is employed in which the first space S1 and the second space S2 are provided, then pressure within the first and the second spaces S1, S2 are decompressed, and on the other hand, only the second space S2 is released from decompression state. The present invention, however, is not limited thereto. In other words, even if an arrangement is employed in which air is supplied only into the space S2, without providing a decompression (vacuum) atmosphere, and the sheet S is stuck to the wafer W through the deformation of the deformable portion 23 and the pressing surface 21, substantially the same sticking of the sheet can be performed.

Further, the plate-like member is not limited to the wafer only, but the above-described embodiment can be also applied to an arrangement in which sheets and films are intended to be stuck to other plate-like members.

Also, the pressing member 12 is comprised of rubber molded components in the above-described embodiment, but not limited thereto. The pressing member 12 may be also comprised of elastically deformable materials such as soft resin materials, metal sheets.

Furthermore, the pressing member 12 is not limited to conical shape, but may be shaped with slopes being formed by two surfaces, alternatively may be arranged so as to stick the sheet S from one end toward the other end. In this case, such arrangement is adaptable by forming, for example, an accordion-shaped deformable portion from peripheral portion of the pressing surface excluding the above-mentioned one end.

Still further, in the above-described embodiment, the second space S2 is formed by the pressing member 12 and the upper case 30 and the mounting cylinder 32, but the second space S2 may be formed with the mounting cylinder being omitted. In addition to this, such arrangement may be employed in which the pressing member 12 itself is constructed to be a balloon-like enclosed shape with an intention to form the second space S2, then an exhaust valve or the like is provided on the pressing member, thereby performing pressure reducing operation.

1. A sheet sticking apparatus comprising: a table for supporting a plate-like member; and a pressing member for exerting a pressing force to a sheet disposed along said plate-like member: wherein
said pressing member includes: a pressing surface arranged to have an inclined surface or a curved-form where central area thereof is closer to said plate-like member than peripheral side; and a deformable portion being continued to a peripheral side of the pressing surface; and wherein
said pressing surface is brought into close proximity with said sheet by causing said deformable portion to be deformed with respect to an initial shape, and said sheet is stuck to the plate-like member from central area toward peripheral side by causing the pressing surface to be deformed so as to be substantially parallel with respect to said plate-like member.

2. A sheet sticking apparatus comprising: a table for supporting a plate-like member; and a pressing member for exerting a pressing force to a sheet disposed along said plate-like member: wherein
said pressing member includes: a pressing surface arranged to have an inclined surface or a curved-form where one end thereof is closer to said plate-like member than the other end; and
a deformable portion being connected to the pressing surface; and wherein
said pressing surface is brought into close proximity with said sheet by causing said deformable portion to be deformed with respect to an initial shape, and said sheet is stuck to the plate-like member from said one end toward the other end by causing said pressing surface to be deformed so as to be substantially parallel with respect to said plate-like member.

3. The sheet sticking apparatus according to claim 1, wherein:
said pressing surface is substantially conical in shape; and
said deformable portion is provided in flexural shape being connected to the peripheral portion of the pressing surface.

4. The sheet sticking apparatus according to claim 1, 2, or 3 further comprising: a lower case of upper open type for accommodating said table; and an upper case of lower open type for accommodating said pressing member, wherein
a first space is formed by said upper and lower cases and the pressing member, whereas a second space is formed by said upper case and the pressing member; and wherein
when said sheet is stuck to the plate-like member by pressing down the sheet, said first and second spaces are kept in decompression or substantially vacuum state, whereas said second space is gradually released from the decompression or substantially vacuum state, thereby causing said deformable portion to be deformed.

5. The sheet sticking apparatus according to claim 1, 2, or 3 further comprising: a lower case of upper open type for accommodating said table; and an upper case of lower open type for accommodating said pressing member: wherein
a first space is formed by said upper and lower cases and the pressing member, whereas a second space is formed by said pressing member; and wherein
when said sheet is stuck to the plate-like member by pressing down the sheet, said first and second spaces are kept in decompression or substantially vacuum state, whereas said second space is gradually released from the decompression or substantially vacuum state, thereby causing said deformable portion to be deformed.

6. The sheet sticking apparatus according to claim 4, wherein
said deformable portion includes zigzag regions, and as said second space is gradually released from decompression or substantially vacuum state, said deformable portion undergoes angular displacement or extensional deformation.

7. The sheet sticking apparatus according to claim 4, wherein
said deformable portion is comprised of such a material that undergoes more readily elastic deformation than said pressing surface, and as said second space is gradually released from decompression or substantially vacuum state, said deformable portion can be so arranged as to undergo elastic deformation.

8. The sheet sticking apparatus according to claim 5, wherein
said deformable portion includes zigzag regions, and as said second space is gradually released from decompression or substantially vacuum state, said deformable portion undergoes angular displacement or extensional deformation.

9. The sheet sticking apparatus according to claim 5, wherein
said deformable portion is comprised of such a material that undergoes more readily elastic deformation than said pressing surface, and as said second space is gradually released from decompression or substantially vacuum state, said deformable portion can be so arranged as to undergo elastic deformation.
